(19) United States
(12) Patent Application Publication
(10) Pub. No.: US 2007/0040189 A1
(43) Pub. Date: Feb. 22, 2007

(54) Bi-directional switch, and use of said switch

(76) Inventors: Stephan Bolz, Pfatter (DE); Rainer Knorr, Regensburg (DE); Norbert Seliger, Munich (DE)

Correspondence Address: STAAS & HALSEY LLP, SUITE 700, 1201 NEW YORK AVENUE, N.W., WASHINGTON, DC, 20005, US

(21) Appl. No.: 10/558,285

(22) PCT Filed: Mar. 18, 2004
(86) PCT No.: PCT/EP04/02853

§ 371 Date: Sep. 8, 2006

(30) Foreign Application Priority Data
May 27, 2003 (DE) 103 24 048.9

(51) Int. Cl. H01L 31/00

(52) U.S. Cl. 257/197

(57) ABSTRACT

A bi-directional switch has at least one first controllable semiconductor component with a first input contact, a first output contact, and a first control contact, and at least one second controllable semiconductor component with a second input contact, a second output contact, and a second control contact. The first input contact of the first semiconductor component and the second input contact of the second semiconductor component are interconnected in an electrically conducting manner, and the first control contact of the first semiconductor component and the second control contact of the second semiconductor component are interconnected in an electrically conducting manner while the first output contact of the first semiconductor component and the second output contact of the second semiconductor component are electrically insulated from each other. The semiconductor components are disposed on a common substrate that is provided with an electrically conducting coating. At least one of said semiconductor components of the switch is arranged on the electrically conducting coating in such a way that a joint contact area corresponding to at least 60 percent of the surface of the contact, which faces the coating, is created between the coating and said surface of the contact, which faces the coating. Said arrangement makes it possible to create a low-impedance, low-inductive bi-directional switch.

### CROSS REFERENCE TO RELATED APPLICATIONS

This application is based on and hereby claims priority to Application No. PCT/EP2004/002853 filed on Mar. 18, 2004 and German Application No. 10324048.9 filed on May 27, 2003, the contents of which are hereby incorporated by reference.

### BACKGROUND OF THE INVENTION

The invention relates to a bidirectional switch and to a use of said bidirectional switch.

In a motor vehicle electrical system with rated voltage of 42V, optimized management of the vehicle electrical system requires suitable switches between an energy storage (battery) and power storage (capacitor) and between a generator and a load (for example a switch as converter for a starter generator). The switches should if required ensure a directed and controlled exchange of power between the different components of the vehicle electrical system. To this end these switches are embodied as bidirectional switches. This means that current can flow in both directions almost independently of the potentials present. What is known as regenerative braking can for example be performed with this type of bidirectional switch. This is done by the starter generator feeding electrical power into a capacitor (a so-called supercap for example) so that when the engine of the motor vehicle is started, it is available as power or available for charging the battery of the motor vehicle.

Usually a mechanical switch or a semiconductor switch is assembled from a plurality of discrete individual components to implement the bidirectional switch. In view of the fact that high currents have to be switched (up to 1 kA) it is desirable to implement the switch with an especially low on-resistance (overall resistance). With modern semiconductor components, especially with MOSFETs with standard connection technology, the proportion of the semiconductor resistance in the overall resistance is not dominant.

Instead bond wires which are used for electrical contacting of the semiconductor component and which in some cases are embodied in multiples in parallel in thick wire bond technology contribute significantly to the overall resistance of the switch.

### SUMMARY OF THE INVENTION

One possible object of the present invention is to specify a bidirectional switch with a low overall resistance by comparison with usual bidirectional switches.

The inventors propose a bidirectional switch, featuring at least a first controllable semiconductor component with a first input contact, a first output contact and a first control contact and at least a second controllable semiconductor component with a second input contact, a second output contact and a second control contact. In this case the first input contact of the first semiconductor component and the second input contact of the second semiconductor component are connected to each other in an electrically-conducting manner and the first output contact of the first semiconductor component and the second output contact of the second semiconductor component are electrically isolated from one another. The semiconductor components of the bidirectional switch are in this case arranged on a joint substrate featuring an electrically-conducting coating. At least one of the semiconductor components of the switch is arranged on the electrically-conducting coating so that a joint contact area of the coating and a surface of the contact facing towards the coating is available, which corresponds to at least 60% of the surface of the contact which faces the coating.

The first control contact of the first semiconductor component and the second control contact of the second semiconductor component can be electrically isolated from one another and thereby controlled separately. Preferably these contacts are connected to each other in an electrically-conducting manner.

The semiconductor component is preferably a power semiconductor component which is suitable for transferring high currents in the kA range. The semiconductor component is preferably a MOSFET. An IGBT or a bipolar transistor is also conceivable. With a bipolar transistor the input contact is usually referred to as the emitter, the output contact as the collector and the control contact as the base, and with a MOSFET accordingly as source, drain and gate.

The substrate functions as a circuit carrier and has a layer made of a dielectric material, onto which the electrically-conducting coating is applied. The dielectric material can be a ceramic or a plastic. The electrically-conducting coating is for example a copper layer. In this case the layer made of the dielectric material can feature an electrically-conducting coating on both sides. This type of substrate is for example what is known as a DCB (Direct Copper Bonding) substrate.

The fact that a coating of the substrate is used for electrical contacting of the contacts of a semiconductor component makes contacting of the input and/or of the output contact over a large area possible. Preferably the resulting contact surface corresponds to at least 80% of the surface of the contact of the semiconductor component facing towards the coating. The contacts electrically contacted in this way are in particular the input and the output contact of the semiconductor component. The result is a bidirectional switch with a significantly lower overall resistance by comparison with the devices. Through suitable measures, for example an electrical strenghening of the coating, a relatively high current carrying capacity can be implemented so that high currents ranging up to several kA can be switched.

In an implementation with MOSFETs, the bidirectional switch is embodied as what is known as a transfer gate. Preferably two transfer gates are interconnected into a module (changeover switch). In this case the bidirectional switch features at least a third controllable semiconductor component with a third input contact, a third output contact and a third control contact and at least a fourth controllable semiconductor component with a fourth input contact, a fourth output contact and a fourth control contact. In this case the third input contact of the third semiconductor component and the fourth input contact of the fourth semiconductor component are connected to each other in an electrically-conducting manner, the third control contact of the third semiconductor component and the fourth control contact of the fourth semiconductor component are connected to each other in an electrically-conducting manner, the third output contact of the third semiconductor component and the fourth output contact of the fourth semiconductor component are electrically isolated from each other and the second output contact of the second semiconductor component and the third output contact of the third semiconductor component are electrically connected to each other.

In a further embodiment at least one further semiconductor component is connected in parallel to at least one of the semiconductor components of the switch. The function of one of the semiconductor components described above is taken over by a plurality of downstream semiconductor components switched in parallel to one another. This reduces the overall resistance of the bidirectional switch.

In a further embodiment the substrate features a cooling device for cooling down at least one of the semiconductor components of the switch. It ensures that the semiconductor components and especially the contacts are cooled efficiently. A good thermal linkage of the semiconductor components to an environment is ensured solely through the large-area contacting of the contacts. The cooling facility further improves the thermal linkage to the environment, which is evident from a reduced temperature increase in operation and thereby in a reduced overall resistance of the bidirectional switch.

The cooling facility is for example a heat sink. The heat sink cools the semiconductor components and/or the electrical contacting by conducting heat. To this end the heat sink can be connected directly or indirectly via the substrate to the semiconductor components. For example the thermal linkage of the semiconductor components is undertaken via the electrically-conducting coating which is connected to the heat sink. Thus the electrically-conducting coating is used not only for electrical contacting, but also for cooling down the semiconductor components. Also conceivable is a cooling facility with a cooling fluid. The cooling fluid can in this case be brought into direct contact with the semiconductor components. It is conceivable for the cooling fluid to be in contact with the heat sink which is connected directly or indirectly to the semiconductor components.

The bidirectional switch presented is generally suitable for power and energy transmission between different electrical components. The switch is used especially for charging and discharging a battery and/or a capacitor. The battery and the capacitor are especially elements of a vehicle electrical system of a motor vehicle. The bidirectional switch is used for control of the vehicle electrical system of a motor vehicle.

The capacitor used in this case is for example a “supercap”.

In summary the proposed switch may be associated with the following advantages:

The large-area contacting of the contacts of the semiconductor components results in a good thermal linkage of the contacts to the environment. The contacting is low-impedance (low loss resistance).

The wide-area contacting also leads to low-inductive electrical contacting. This has a positive effect on an EMC (electromagnetic compatibility) behavior of the switch.

The heating of the semiconductor components and thereby the electrical contacting can be minimized through the integration of a cooler. This further improves the low-impedance electrical contacting of the semiconductor components.

The outstanding feature of the bidirectional switch is its high current carrying capacity.

As a result of the good thermal linkage low temperature gradients and thereby low thermodynamic loads occur in the arrangement.

The result is a more compact design which leads to a high reliability of the bidirectional switch.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

The figures are schematic and do not represent true-to-scale illustrations.

FIGS. 1 to 3 each show overhead views of circuit arrangements of a bidirectional switch on a substrate.

FIG. 4 shows a block diagram of the bidirectional switch of FIGS. 1 to 3.

FIGS. 5 and 7 to 9 each show overhead views of an arrangement of a bidirectional switch in the form of a changeover switch with two transfer gates on a substrate.

FIG. 6 shows a block diagram of the bidirectional switch of FIGS. 5 and 7 to 9.

FIG. 10 shows a section of an arrangement of a bidirectional switch on a substrate in a cross-section from the side.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

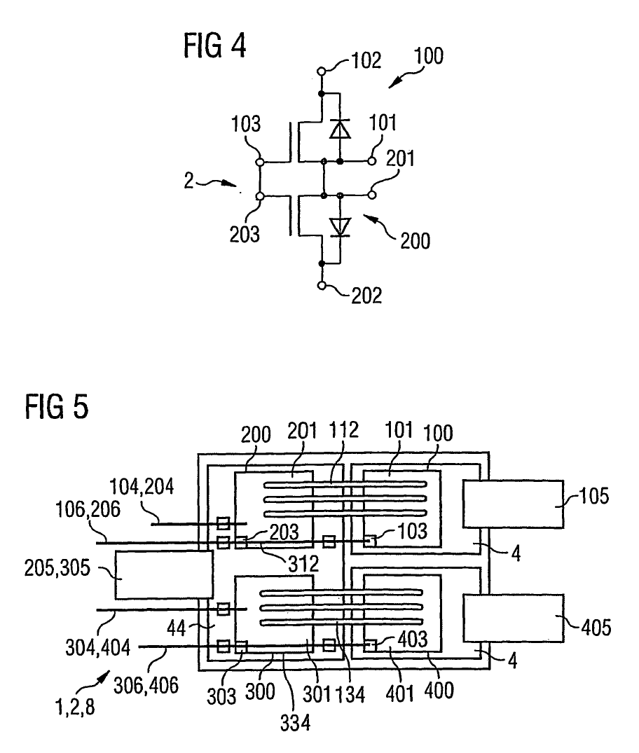

An arrangement 1 of a bidirectional switch 2 on a substrate 3 is produced. Switch 2 features at least a first controllable semiconductor component 100 with a first input contact 101, a first output contact 102 and a first control contact 103 and at least a second controllable semiconductor component 200 with a second input contact a second output contact 202 and a second control contact 203 (cf. FIG. 4). In this case the first input contact 101 of the first semiconductor component 100 and the second input contact 201 of the second semiconductor component 200 are connected to each other in an electrically-conducting manner, the first control contact 103 of the first semiconductor component 100 and the second control contact 203 of the second semiconductor component 200 are connected to each other in an electrically-conducting manner and the first output contact 102 of the first semiconductor component 100 and the second output contact 202 of the second semiconductor component 200 are electrically isolated from each other. At least one of the semiconductor components 100, 200 of the switch 2 is arranged on the electrically-conducting coating such that a shared contact surface 5 of the coating 4 and of a surface 6 of the contact facing towards the coating 4 is present which corresponds to at least 80% of the surface 6 facing towards the contact.

The semiconductor components are MOSFETs with a surface of the input (source) or output (drain) contact of around 60 mm². These MOSFETs are arranged, so that up to 300 A can be continuously switched. Up to 1 kA switching current can be switched for 100 ms to 200 ms by the bidirectional switches. Up to 600 A can be switched for around 8 s.

The substrate is DCB substrate with a ceramic layer which is provided on both sides with an electrically-conducting coating made of copper. The ceramic layer in this case forms the actual substrate 3 which features the electrically-conducting coatings 4 and 48 (cf. FIG. 10). The coating 4 and the contact of the semiconductor component 100, 200, 300 or 400 feature a joint contact area 5. The joint contact area 5 is formed by the surface 6 of the contact of the semiconductor component facing towards the coating 4.

The contact of the semiconductor component facing away from the coating is contacted by bond wires, or as shown in FIG. 10, over a wide area. To this end an electrically-conducting foil, 43, 45, 46 or 47 reinforced by electrically deposited copper, is used. An isolating foil 10 ensures electrical isolation of the contacts of the semiconductor component from each other.

The substrate 3 features two heat sinks 7. The heat sink 7 is connected to the substrate with a connector 9 in the form of a screw connection such that the semiconductor components can be cooled in operation. In an alternative embodiment the connection is a terminal. Between the heat sink 7 and the substrate 3 an (electrically isolating) heat-conducting paste 11 in the form of a molding compound is arranged, so that heat generated during operation of the bidirectional switch can be efficiently removed. In combination with this or as an alternate, the heat sink 7 and the substrate 3 or the coatings 4 and 48 of the substrate 3 are soldered to each other. The solder forms the heat-conducting contact between the heat sinks and the coating of the substrate. Alternatively in further embodiments a heat-conducting paste is used instead of the solder and a heat-conducting foil is provided as an alternate.

### Exemplary Embodiment 1

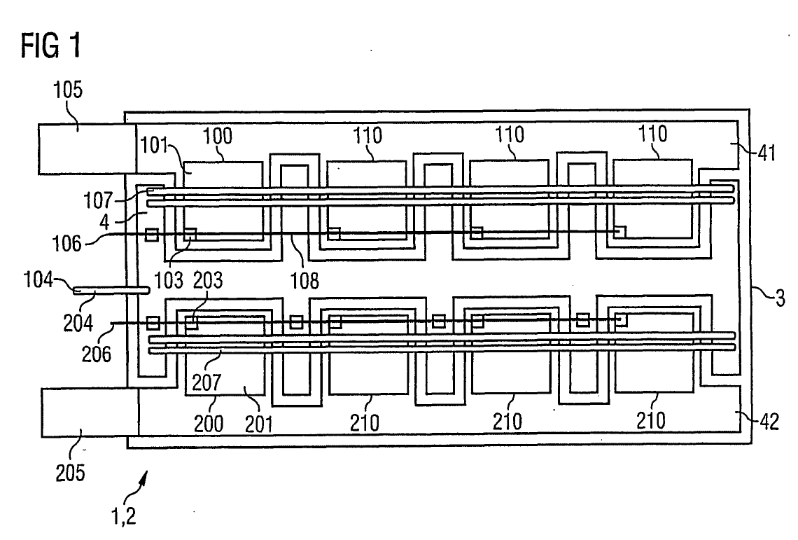

Bidirectional switch 2 forms a single transfer gate (FIG. 1, FIG. 4). The first semiconductor component 100 is arranged on a first coating 41 of the substrate 3 such that the output contact 102 of the first semiconductor component 100 which is not visible in the drawing is connected in an electrically-conducting manner over a large area with the first coating 41 and via this to the first output connection 105. The first output connection 105 serves as a load connection of the first semiconductor component 100. Also shown is the exposed first control contact 103 of the first semiconductor component 100, which is electrically connected to the first control connection 106. Three further first semiconductor components 110 are switched in parallel to the first semiconductor component 100. This is implemented such that the first output contacts of the first semiconductor components are connected to each other in an electrically-conducting manner via the first electrically-conducting coating 41, the first input contacts of the first semiconductor components via bond wires 107 and the first control contacts of the first semiconductor components via a bond wire 108.

The second semiconductor component 200 is arranged on a second coating 42 of the substrate 3 such that the output contact 203 of the second semiconductor component 200 which is not visible is connected over a large area in an electrically conducting manner to the second coating 42 and via this to the second output connection 205. The second output connection 205 serves as a load connection of the second semiconductor component 200. The second control contact 203 of the second semiconductor component 200 is electrically connected to the first control connection 106. Three further second semiconductor components 210 are switched in parallel to the second semiconductor component 200. This is implemented such that the second output contacts of the second semiconductor components are connected to each other in an electrically-conducting manner via the second electrically-conducting coating 42, the second input contacts of the second semiconductor components via bond wires 207 and the second control contacts of the second semiconductor components via a bond wire 208.

The first input contact 101 of the first semiconductor component 100 or the first input contact of first semiconductor components 100 and 110 are connected in an electrically-conducting manner via the electrically-conducting coating 4 of the substrate to the second input contact 201 of the second semiconductor component 200 or the second input contact of the second semiconductor components 200 and 210. The first input connection 104 and the second input connection 204 are identical.

In addition the first and second control contacts 103 and 203 of the first and second semiconductor components 100, 110 and 210 are connected to each other in an electrically-conducting manner. To this end the first control connection 106 and the second control connection 206 are connected to each other in an electrically-conducting manner. This is not shown in FIG. 1.

### Exemplary Embodiment 2

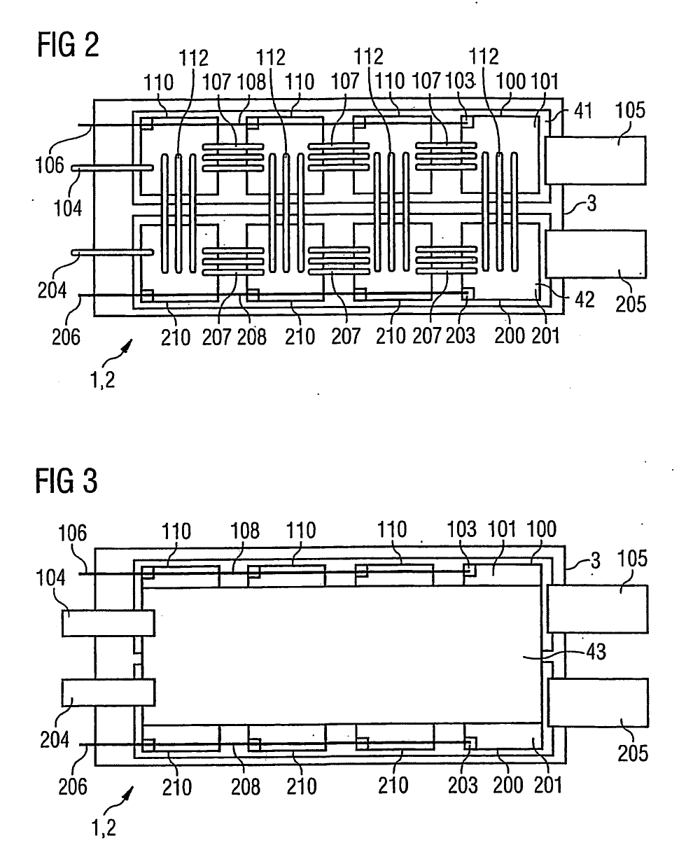

By contrast with the previous exemplary embodiment the first input contacts of the first semiconductor components 100, 110 and the second input contacts of the second semiconductor components 210 are connected to each other in an electrically-conducting manner not via a coating 4 of the substrate 3, but via further bond wires 112 (FIG. 2).

### Exemplary Embodiment 3

Unlike in the previous exemplary embodiments, no bond wires 112 are used for electrical contacting of the first input contacts of the first semiconductor components 100, 110 with the second input contacts of the second semiconductor components 210, (FIG. 3). The input contacts are contacted over a large area via an electrically-conducting foil 43 and connected to each other in an electrically-conducting manner. At least 60% of the surface of an input contact is connected in an electrically-conducting manner in this case with the foil 43 and forms a joint contact surface. To increase the current-carrying capacity of the foil 43 copper is electrically deposited on the foil. Foils made from a dielectric material are used for electrical isolation from the background, for example from the electrically-conducting coatings 41 and 42.

As shown, bond wires 108 and 208 can be used for electrical contacting of the control contacts. As an alternative the control contacts are also contacted with each other by an electrically-conducting foil.

### Exemplary Embodiment 4

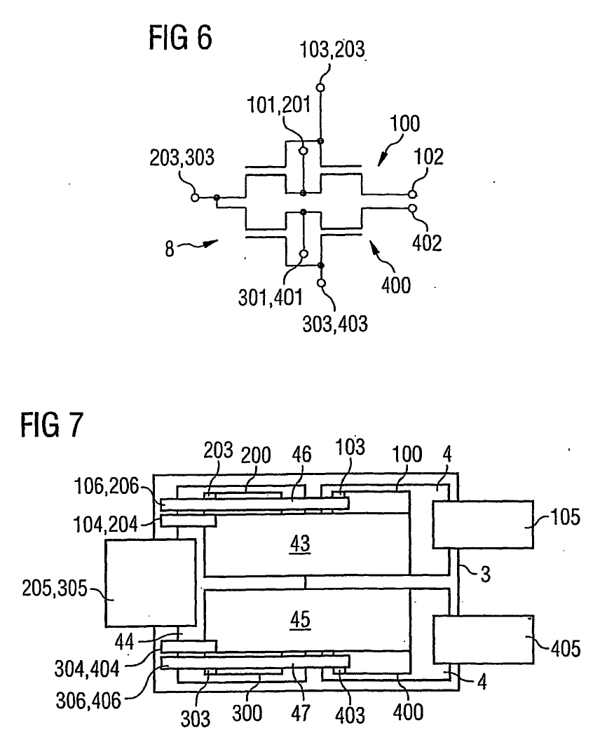

The bidirectional switch 2 forms two transfer gates which are connected together to form a changeover switch 8. FIG. 6 shows the corresponding equivalent circuit diagram. To aid clarity the internal diodes. The MOSFETs are not shown in this figure.

To implement the changeover switch a third controllable semiconductor component 300 with a third input contact 301, a third output contact 302 and a third control contact 303 and a fourth controllable semiconductor component 400 with a fourth input contact 401, a fourth output contact 402 and a fourth control contact 403 are present (FIG. 5). The third input contact 301 of the third semiconductor component 300 and the fourth input contact 401 of the fourth semiconductor component 400 are connected to each other in an electrically conducting manner via bond wires 134. The third control contact 303 of the third semiconductor component 300 and the fourth control contact 403 of the fourth semiconductor component 400 are connected to each other in an electrically-conducting manner via a bond wire 334. The third output contact 303 of the third semiconductor component 300 and the fourth output contact 403 of the fourth semiconductor component 400 are electrically isolated from each other. By contrast the second output contact 202 of the second semiconductor component 200 and the third output contact 302 of the third semiconductor component 300 are connected to each other in an electrically-conducting manner via a coating 44 of the substrate 3.

The second output connection 205 and the third output connection 305 are identical. Likewise the first and second input connection 104 and 204 are identical. The same then applies to the first and second control connection 106 and 206 and to the third and fourth control connection 306 and 406.

### Exemplary Embodiment 5

Electrically-conducting foils 43 and 45 are used for electrical contacting of the first and second input contact or of the third and fourth input contact (FIG. 7, cf. exemplary embodiment 3). These foils are strengthened by electrical deposition of copper. The first and second control contact 103 and 203 are electrically contacted over a large area via an electrically-conducting foil 46 and the third and fourth control contacts 303 and 304 electrically contacted over a large area via an electrically-conducting foil 47.

### Exemplary Embodiment 6

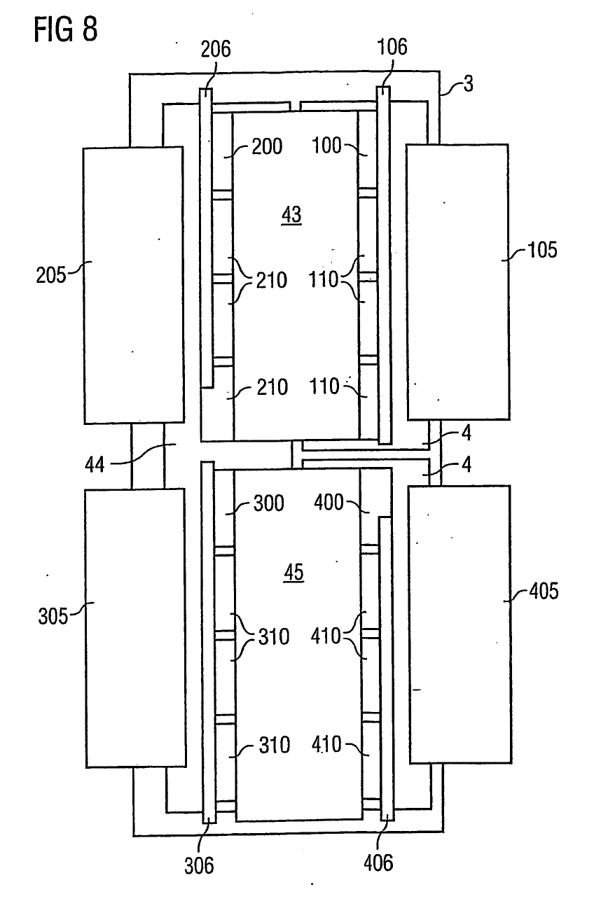

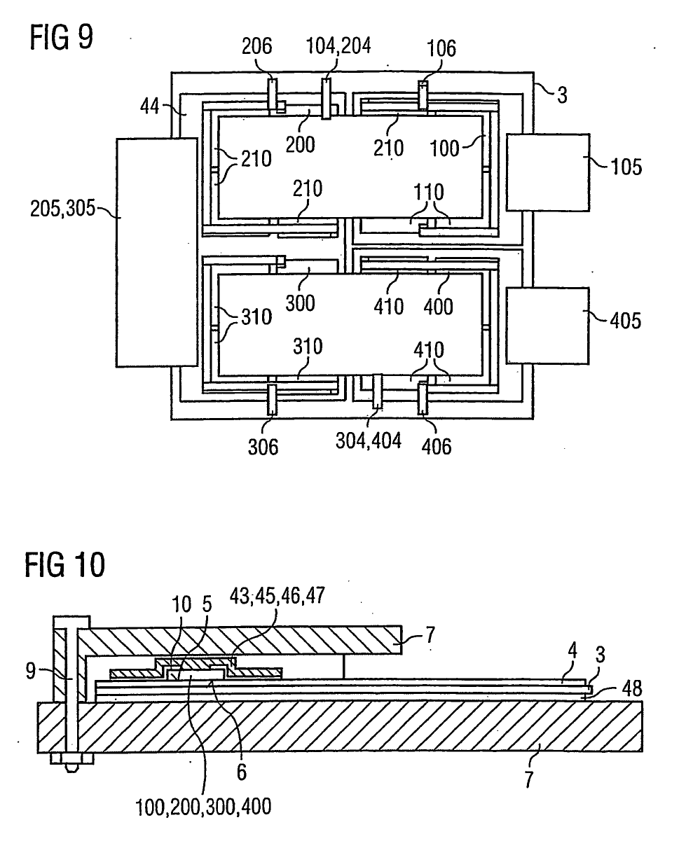

In a development of the previous exemplary embodiment three further semiconductor components 210, 310 and 410 are switched in parallel to each of the semiconductor components 100, 200, 300 and 400 (FIGS. 8 and 9). The quadratic arrangement of the semiconductor components in accordance with FIG. 9 results is a more favorable heat distribution during the operation of the changeover switch 8 by comparison with the arrangement shown in FIG. 8. A thermal stress caused by the operation of the changeover switch is less.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-10. (canceled)

11. A bidirectional switch comprising:
at least a first controllable semiconductor component that includes a first input contact, a first output contact, and a first control contact; and
at least a second controllable semiconductor component that includes a second input contact, a second output contact, and a second control contact, wherein:
the first input contact of the first semiconductor component and the second input contact of the second semiconductor component are connected to each other in an electrically-conducting manner;
the first output contact of the first semiconductor component and the second output contact of the second semiconductor component are electrically isolated from each other;
the semiconductor components are arranged on a substrate which includes an electrically-conducting coating; and
at least one of the semiconductor components includes a component contact surface facing towards the coating and is arranged on the electrically-conducting coating such that a joint contact surface of the coating and the component contact surface is present and corresponds to at least 60% of the component contact surface.

12. The switch in accordance with claim 11, wherein
the first control contact of the first semiconductor component and the second control contact of the second semiconductor component are connected to each other in an electrically-conducting manner.

13. The switch in accordance with claim 11, wherein
the joint contact surface corresponds to at least 80% of the component contact surface.

14. The switch in accordance with claim 11, wherein
the first input contact of the first semiconductor component and the second input contact of the second semiconductor component are connected to each other in an electrically conducting manner by the electrically-conducting coating of the substrate.

15. The switch in accordance with claim 11, further comprising:
at least a third controllable semiconductor component that includes a third input contact, a third output contact, and a third control contact; and
at least a fourth controllable semiconductor component that includes a fourth input contact, a fourth output contact, and a fourth control contact, wherein:
the third input contact of the third semiconductor component and the fourth input contact of the fourth semiconductor component are connected to each other in an electrically-conducting manner;
the third control contact of the third semiconductor component and the fourth control contact of the fourth semiconductor component are connected to each other in an electrically-conducting manner;
the third output contact of the third semiconductor component and the fourth output contact of the fourth semiconductor component are electrically isolated from each other; and
the second output contact of the second semiconductor component and the third output contact of the third semiconductor component are connected to each other in an electrically-conducting manner.

16. The switch in accordance with claim 11, further comprising
at least a further semiconductor component that is switched in parallel to at least one of the semiconductor components of the switch.

17. The switch in accordance with claim 11, wherein
at least one of the semiconductor components of the switch is a MOSFET, IGBT, or bipolar transistor.

18. The switch in accordance with claim 11, wherein
the substrate includes a cooling facility for cooling at least one of the semiconductor components.

19. A method comprising
using the switch of any one of claims 11-18 for charging and discharging a battery and/or capacitor with an electrical charge.

20. The method in accordance with claim 19, wherein
the battery and/or capacitor is part of a motor vehicle electrical system.
